(19) United States
(12) Patent Application Publication
(10) Pub. No.: US 2013/0069207 A1
(43) Pub. Date: Mar. 21, 2013

(54) METHOD FOR PRODUCING A DEPOSIT AND A DEPOSIT ON A SURFACE OF A SILICON SUBSTRATE

(71) Applicant: Jarmo Skarp, Espoo (FI)

(72) Inventor: Jarmo Skarp, Espoo (FI)

(73) Assignee: Beneq Oy, Vantaa (FI)

(21) Appl. No.: 13/639,184

(22) PCT Filed: May 6, 2011
(86) PCT No.: PCT/FI2011/050417

§ 371 Date: Oct. 3, 2012

(30) Foreign Application Priority Data
May 10, 2010 (FI) 20105498

(51) Int. Cl. H01L 21/02

(52) U.S. Cl. CPC H01L 21/0228; H01L 21/02178
USPC 257/632; 438/778

(57) ABSTRACT

A deposit and a method for producing a deposit on a surface of a silicon substrate. The deposit comprises aluminum oxide, and the method comprises in any order the alternating steps of a) introducing into a reaction space one of water and ozone as a precursor for oxygen, b) introducing into a reaction space the other of water and ozone as a precursor for oxygen, c) introducing into a reaction space a precursor for aluminum and subsequently purging the reaction space;with the provisions that when step a) or step b) precedes step c) then the reaction space is purged before step c), and that the reaction space is not purged between step a) and step b), when step a) precedes step b) or when step b) precedes step a).

### FIELD OF THE INVENTION

The present invention relates to a method for producing a deposit comprising aluminum oxide on a surface of a silicon substrate. Further, the invention relates to a deposit on a surface of a silicon substrate.

### BACKGROUND OF THE INVENTION

Atomic Layer Deposition (ALD) is a well known method for producing deposits of material over substrates of various shapes. In an ALD process two or more different chemicals (precursors) are introduced to a reaction space in a sequential, alternating, manner and the chemicals adsorb on surfaces, e.g. on a substrate, inside a reaction space.

The sequential, alternating, introduction of chemicals or precursors is commonly called pulsing or dosing (of chemicals or precursors). In between each chemical pulse there is commonly a purging period during which a flow of gas which does not react with the chemicals used in the process is introduced through the reaction space. This gas, often called the carrier gas or purge gas, is therefore inert towards the chemicals used in the process and purges the reaction space from e.g. surplus chemical and by-products resulting from reactions between the surface and the previous chemical pulse. This purging can be arranged also by other means, and the deposition method can be called by other names such as ALE (Atomic Layer Epitaxy), ALCVD (Atomic Layer Chemical Vapor Deposition), cyclic vapour deposition etc. The essential feature of these methods is to sequentially expose the deposition surface to precursors and to growth reactions of precursors essentially on the deposition surface. In this specification, unless otherwise stated, these processes will be collectively addressed as ALD-type processes.

A deposit of desired thickness can be grown by an ALD process by repeating several times a pulsing sequence comprising the aforementioned pulses containing the precursor material, and the purging periods. The number of how many times this sequence, called the “ALD cycle”, is repeated depends on the targeted thickness.

Surface recombination on semiconducting surfaces can present a problem in applications for ALD processes, which include semiconductor devices such as photovoltaic cells or light emitting diodes. In these applications surface recombination can lead to trapping of charge carriers in specific energy states at or close to the surface of a semiconductor, for example. These energy states, or surface states as they are often called, may originate for example from impurities at the surface.

A promising material candidate for passivating i.e. for reducing surface recombination of a silicon surface is aluminum oxide.

Prior art, for example U.S. Pat. No. 7,476,420, recognizes the use of trimethylaluminum (TMA) and ozone (O₃) in an ALD-cycle for growing aluminum oxide for rear surface passivation (RSP) of a surface of a substrate with good passivation properties of the produced deposit. However, problems arise with the growth rate depending on the concentration of ozone and/or the processing temperature. In order to achieve a uniform growth rate and a uniform thickness profile with a reasonable pulse time a high concentration of ozone in a pulse is usually needed.

Further, the use of TMA and water for growing aluminum oxide on a silicon surface by an ALD-process is known to the skilled person. Here, the aluminum oxide layer grows uniformly but results in poor passivation properties of the produced deposit on a silicon surface.

### PURPOSE OF THE INVENTION

A purpose of the invention is to solve the aforementioned technical problems of the prior art by providing a new type of method for producing a deposit comprising aluminum oxide on the surface of a silicon substrate. Further, a purpose of the invention is to provide a deposit on a surface of a silicon substrate.

### SUMMARY OF THE INVENTION

The method according to the present invention is characterized by what is presented in claim 1.

The deposit on a surface of a silicon substrate according to the present invention is characterized by what is presented in claim 13.

The method according to the present invention for producing a deposit on a surface of a silicon substrate, where the deposit comprises aluminum oxide, comprises in any order the alternating steps of

a) introducing into a reaction space one of water and ozone as a precursor for oxygen such that at least a portion of said precursor for oxygen gets adsorbed onto the deposition surface of the silicon substrate,

b) introducing into a reaction space the other of water and ozone as a precursor for oxygen such that at least a portion of said precursor for oxygen gets adsorbed onto the deposition surface of the silicon substrate,

c) introducing into a reaction space a precursor for aluminum such that at least a portion of the precursor for aluminum gets adsorbed onto a deposition surface of the silicon substrate, and subsequently purging the reaction space,

with the provisions that when step a) or step b) precedes step c) then the reaction space is purged before step c), and that the reaction space is not purged between step a) and step b), when step a) precedes step b) or when step b) precedes step a).

According to one embodiment of the present invention for producing a deposit on a surface of a silicon substrate, where the deposit comprises aluminum oxide, comprises in any order the steps of

a) introducing into a reaction space one of water and ozone as a precursor for oxygen such that at least a portion of said precursor for oxygen gets adsorbed onto the deposition surface of the silicon substrate,

b) introducing into a reaction space the other of water and ozone as a precursor for oxygen such that at least a portion of said precursor for oxygen gets adsorbed onto the deposition surface of the silicon substrate,

c) introducing into a reaction space a precursor for aluminum such that at least a portion of the precursor for aluminum gets adsorbed onto a deposition surface of the silicon substrate, and subsequently purging the reaction space,

with the provision that when step a) or step b) precedes step c) then the reaction space is purged before step c).

According to one embodiment of the present invention step a), step b) and step c) are performed in an alternate manner, i.e. these steps do not markedly overlap in time. Thus according to one embodiment of the present invention step a), step b) and step c) are performed as sequential, distinct steps. According to one embodiment of the present invention step a) and step b) do not overlap in time.

According to one embodiment of the present invention the purpose of the invention is to produce a passivating deposit on the surface of a silicon substrate. In this specification the expression “passivation”, “surface passivation” or other corresponding expressions should be understood as the passivation of a surface for reducing surface recombination, i.e. for reducing the recombination of charge carriers on, or in immediate proximity to, the passivated surface, i.e. the surface of the silicon substrate.

The method according to the present invention for producing a deposit is based on the use of two different precursors for oxygen, i.e. water and ozone, together with a precursor for aluminum in the same

ALD-cycle for the production of a deposit comprising aluminum oxide.

According to one embodiment of the present invention step a) and step b) can be performed at least partially simultaneously. In other words, water and ozone can be introduced into the reactor space at least partially simultaneously. According to one embodiment of the present invention both precursors for oxygen, i.e. water and ozone, can be introduced simultaneously into the reaction space.

According to one embodiment of the present invention step a) and step b) are performed sequentially in any order. In other words, the precursors for oxygen, i.e. water and ozone, are introduced into the reaction space one after the other in any order. According to one embodiment of the present invention step a) comprising introducing water as a precursor for oxygen is performed before step b) comprising introducing ozone as a precursor for oxygen. Without limiting the invention to any specific mechanism, it is assumed that when ozone is introduced into the reaction space after the introduction of water, ozone removes possible impurities, e.g. OH and C, left in the reaction space from the introduction of water.

According to the present invention the reaction space is not purged between step a) and step b), when step a) precedes step b) or when step b) precedes step a). This means that the reaction space will comprise at least a portion of the precursor for oxygen firstly introduced into the reaction space when the introduction of the other precursor for oxygen to the reaction space is began.

The method according to the invention comprises the provision that when step a) or step b) precedes step c) then the reaction space is purged before step c). This provision ensures that the reaction space is purged from other chemicals before introducing the precursor for aluminum into the reactor space.

At least a portion of the introduced precursor gets adsorbed onto the deposition surface of the silicon substrate. In this specification, unless otherwise stated, the term “surface of the silicon substrate”, “surface of the substrate”, “the surface” or “deposition surface” is used to address the surface of the substrate or the surface of the already formed deposit on the substrate. I.e. the term “deposition surface” should be understood as including also the surface of the substrate, which has not yet been exposed to any precursor as well as the surface, which has been exposed to one or more precursors. Hence the “deposition surface” changes during the method of forming a deposit on the substrate when chemicals get adsorbed onto the surface.

According to one embodiment of the invention the surface of the silicon substrate comprises monocrystalline silicon. According to another embodiment of the invention the surface of the silicon substrate comprises polysilicon. According to a further embodiment of the invention the surface of the silicon substrate comprises microcrystalline silicon.

According to one embodiment of the invention the deposit is produced on the surface of the silicon substrate in a reaction space by an ALD-type process. According to another embodiment of the invention growth of the deposit in the ALD-type process is essentially thermally activated. When the deposit is fabricated on the surface of the silicon substrate by an ALD-type process excellent conformality and uniformity is achieved for the deposit. Furthermore, the possible desired passivation effect is enhanced when the ALD-type process is essentially thermally activated, i.e. no plasma activation is employed.

According to one embodiment of the present invention the precursor for aluminum is selected from the group of organometallic chemicals comprising aluminum. According to one embodiment of the present invention the precursor for aluminum is selected from the group of trimethylaluminum and triethylaluminum. In one embodiment of the invention the precursor for aluminum comprises trimethylaluminum.

Further, according to one embodiment of the present invention the method comprises repeating at least once at least one of step a), step b) and step c). For example, step a), step b) and step c) can be repeated at least once in any order in series. The thickness of the deposit comprising aluminum oxide can be increased in some embodiments of the present invention by repeatedly introducing the precursors into the reaction space such that a portion of them adsorbs onto the exposed surfaces in the reaction space, i.e. onto the deposition surfaces. In this way the passivation effect may be enhanced in some embodiments of the invention.

According to one embodiment of the present invention the deposit on the surface of the silicon substrate is a passivating deposit. The passivating deposit passivates, i.e. reduces surface recombination of the surface of the silicon substrate. I.e. according to one embodiment of the present invention the method comprises producing a passivating deposit on a surface of a silicon substrate.

Further, the invention relates to a deposit on a surface of a silicon substrate, where the deposit comprises aluminum oxide and where the deposit on a surface of a silicon substrate is obtained by a method according to any of the above embodiments of the present invention.

According to one embodiment of the present invention the deposit on the surface of the silicon substrate is a passivating deposit. The passivating deposit passivates, i.e. reduces surface recombination of the surface of the silicon substrate.

It was observed that a surprisingly good passivation effect was achieved together with a compositionally uniform deposit with also a uniform thickness profile when using water and ozone precursors for oxygen in the same ALD-cycle together with the precursor for aluminum. This advantageous combination of good passivation and uniformity of the produced deposit can be utilized in many applications, for example in thin-film silicon solar cells.

The embodiments of the invention described hereinbefore may be used in any combination with each other. Several of the embodiments may be combined together to form a further embodiment of the invention. A method or a product, to which the invention is related, may comprise at least one of the embodiments of the invention described hereinbefore.

An advantage of the method according to the present invention is that the method surprisingly combines good passivation properties with good growth uniformity.

An advantage of the method according to the present invention is that a good growth rate of about 1.2 Å/c (Angstrom per one ALD-cycle) can be achieved together with good thickness uniformity of the produced deposit.

An advantage of the method according to the present invention is that since ozone requires a shorter purging time than water, the introduction of ozone into the reaction space after water as precursor for oxygen does not increase the total cycle time compared to using water as sole precursor for oxygen in a similar ALD-cycle.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings;

FIG. 1 is a flow chart illustration of a method according to one embodiment of the present invention,

FIG. 2 is a flow chart illustration of a method according to one embodiment of the present invention,

FIG. 3 schematically presents one ALD-cycle in a method according to one embodiment of the present invention, and

FIG. 4 presents data of excess carrier lifetime measurements (QSSPC-measurements).

### DETAILED DESCRIPTION OF THE INVENTION

Reference will now be made in detail to the embodiments of the present invention, examples of which are illustrated in the accompanying drawings.

The description below discloses some embodiments of the invention in such a detail that a person skilled in the art is able to utilize the invention based on the disclosure. Not all steps of the embodiments are discussed in detail, as many of the steps will be obvious for the person skilled in the art based on this specification.

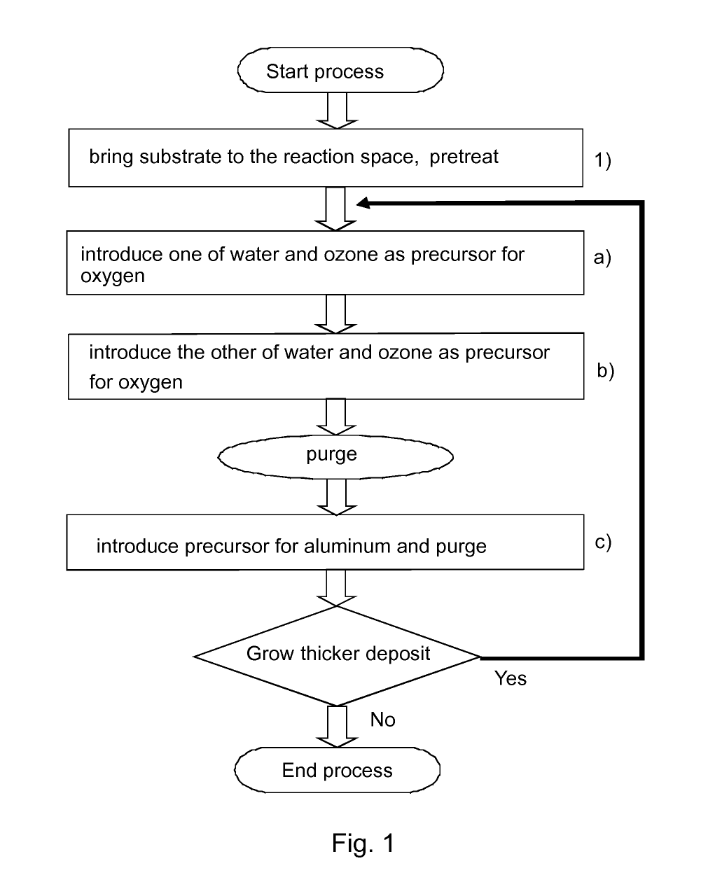

FIG. 1 illustrates a method according to one embodiment of the present invention for the production of a deposit comprising aluminum oxide on the surface of a silicon substrate.

Before the silicon substrate is brought into the reaction space, the surface of the silicon substrate can be conditioned. This conditioning of the surface of the silicon substrate may include chemical purification of the surface of the silicon substrate from impurities. The ex-situ conditioning may include etching for 1 min in a 1% HF solution followed by rinsing in DI-water. The details of the process for removing impurities from the surface of the silicon film will be obvious to the skilled person. In some embodiments of the invention the conditioning can be done in-situ, i.e. inside the tool suitable for ALD-type processes.

After the possible conditioning the silicon substrate is brought into the reaction space (step 1) of a typical reactor tool, e.g. a tool suitable for carrying out an ALD-type process.

The reaction space is subsequently pumped down to a pressure suitable for forming a deposit, using e.g. a mechanical vacuum pump, or in the case of atmospheric pressure ALD systems and/or processes, flows are typically set to protect the deposition zone from the atmosphere. The substrate is also heated to a temperature suitable for forming the deposit by the used method. The silicon substrate can be introduced to the reaction space through e.g. an airtight load-lock system or simply through a loading hatch. The substrate can be heated by e.g. resistive heating elements which also heat the entire reaction space.

After the surface of the silicon substrate and the reaction space have reached the targeted temperature and other conditions suitable for deposition, an alternate exposure of the deposition surface to different chemicals is started, to form a deposit comprising aluminum oxide directly on the surface of the silicon substrate.

The precursors are suitably introduced into the reaction space in their gaseous form. This can be realized by first evaporating the precursors in their respective source containers which may or may not be heated depending on the properties of the precursor chemical itself. The evaporated precursor can be delivered into the reaction space by e.g. dosing it through the pipework of the reactor tool comprising flow channels for delivering the vaporized precursors into the reaction space. Controlled dosing of vapor into the reaction space can be realized by valves installed in the flow channels or other flow controllers. These valves are commonly called pulsing valves in a system suitable for ALD-type deposition. Also other mechanisms of bringing the substrate into contact with a chemical inside the reaction space may be conceived. One alternative is to make the surface of the substrate (instead of the vaporized chemical) move inside the reaction space such that the substrate moves through a region occupied by a gaseous chemical.

A typical reactor suitable for ALD-type deposition comprises a system for introducing carrier gas, such as nitrogen or argon into the reaction space such that the reaction space, e.g. the deposition chamber, if needed, be purged from surplus chemical and reaction by-products before introducing the next chemical into the reaction space. In practice the flow of carrier gas is commonly continuous through the reaction space throughout the deposition process and only the various precursors are alternately introduced to the reaction space with the carrier gas. Obviously, purging of the reaction space does not necessarily result in complete elimination of surplus precursors or reaction by-products from the reaction space but residues of these or other materials may always be present.

Following the step of various preparations and pretreatments (step 1) discussed above), in the embodiment of the present invention shown in FIG. 1, step a), step b) and step c) are carried out. Firstly step a) is carried out, i.e. the deposition surface of the substrate is exposed to one of water, H₂O, and ozone, O₃, as a first precursor for oxygen. Exposure of the surface to the first precursor for oxygen results in the adsorption of a portion of the introduced precursor onto the surface of the silicon substrate.

Subsequently step b) is carried out, i.e. the other of water and ozone as a second precursor for oxygen is introduced to the reaction space without any preceding purging of the reaction space. At least a portion of the second precursor for oxygen in turn gets adsorbed onto the surface resulting from step a).

Subsequently, the reaction space is purged in accordance with the present invention before introducing the precursor for aluminum (in step c)) into the reaction space. The precursor for aluminum can be e.g. trimethylaluminum (TMA). Subsequently the reaction space is purged.

As a result of steps a), b) and c), a deposit comprising aluminum oxide on the surface of the silicon substrate is formed.

Each exposure of the deposition surface to a precursor in steps a), b) and c), according to the embodiment of FIG. 1, results in formation of additional deposit on the deposition surface as a result of adsorption reactions of the corresponding precursor with the deposition surface. Thickness of the deposit on the surface of the silicon substrate can be increased by repeating the steps a), b) and c), as presented by the flow-chart of FIG. 1. The thickness of the deposit is increased until a targeted thickness is reached, after which the alternate exposures are stopped and the process is ended. As a result of the deposition process a deposit comprising aluminum oxide is formed on the surface of the silicon substrate. The deposit has excellent thickness uniformity and compositional uniformity along the deposition surface.

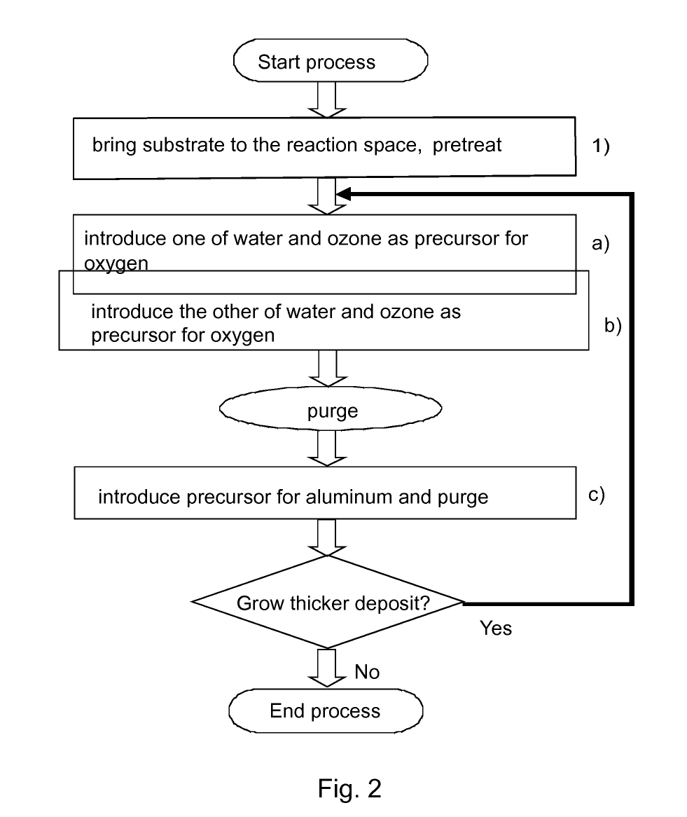

FIG. 2 illustrates a method according to a second embodiment of the present invention for the production of a deposit comprising aluminum oxide on the surface of a silicon substrate.

Again, this second exemplary embodiment of the present invention begins with bringing the silicon substrate into the reaction space (step 1) of a typical reactor tool suitable for carrying out an ALD-type process. The reaction space, the substrate and the chemicals to be introduced into the reaction space are prepared as discussed above in order to be suitable for the deposition process.

Following the step of pretreatment (step 1), in the embodiment of the present invention shown in FIG. 2, step a) is carried out, i.e. the surface of the silicon substrate, i.e. the deposition surface, is exposed to one of water and ozone as a first precursor for oxygen. Exposure of the surface to the first precursor for oxygen results in the adsorption of a portion of the introduced precursor onto the surface of the silicon substrate.

After a predetermined time of introducing one of water and ozone as the first precursor for oxygen, the introduction of the other of water and ozone as a second precursor for oxygen is simultaneously began (step b)). At least a portion of the second precursor for oxygen gets adsorbed onto the deposition surface together with the first precursor for oxygen. In other words, at least a portion of water and at least a portion of ozone are adsorbed onto the deposition surface. After a predetermined time of simultaneous introduction of water and ozone, the introduction of the first precursor for oxygen is terminated while the introduction of the second precursor for oxygen is continued for a predetermined time.

In another embodiment of the present invention, after simultaneous introduction of the first and the second precursors for oxygen, the introduction of the second precursor for oxygen can be terminated while the introduction of the first precursor for oxygen can be continued for a predetermined time.

Subsequently, the reaction space is purged before introducing the precursor for aluminum (step c)) into the reaction space. A precursor for aluminum can be e.g. trimethylaluminum (TMA). Subsequently the reaction space is purged.

As a result of steps a), b) and c), a deposit comprising aluminum oxide on the surface of the silicon substrate is formed.

Again, each exposure of the deposition surface to a precursor in steps a), b) and c), according to the embodiment of FIG. 2, results in formation of additional deposit on the deposition surface as a result of adsorption reactions of the corresponding precursor with the deposition surface. Thickness of the deposit on the surface of the silicon substrate can be increased by repeating the steps a), b) and c), as presented by the flow-chart of FIG. 2. The thickness of the deposit is increased until a targeted thickness is reached, after which the exposures are stopped and the process is ended. As a result of the deposition process a deposit comprising aluminum oxide is formed on the surface of the silicon substrate.

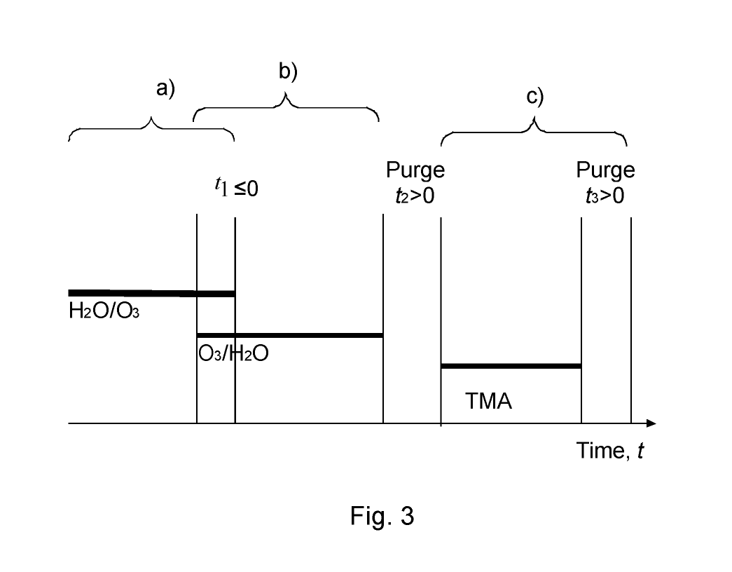

FIG. 3 presents a method according to one embodiment of the present invention. In FIG. 3 the process steps are shown as a function of time. By the interval of t₁ is meant that the two different precursors for oxygen, i.e. water and ozone, can be introduced to the reaction space one after the other without purging of the reaction space in between or at least partially simultaneously or simultaneously. t₂ and t₃ present that the reaction space is purged for a predetermined time between step b) and step c) and during the end of step c). The duration of t₁, t₂ and t₃ can be independently chosen. Step c) could in equal manner begin the process and be followed by step a) or step b) as is clear for a skilled person based on the present specification. The duration of each of the process steps can be independently chosen as is clear for a skilled person.

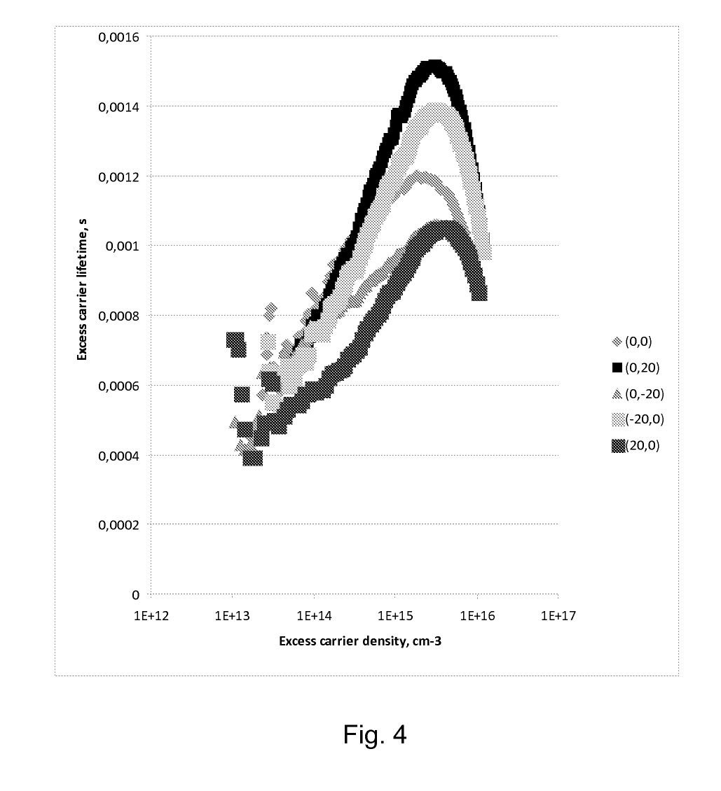

FIG. 4 illustrates data of excess carrier lifetime measurements (QSSPC measurement). The surface of silicon is illuminated with a pulsing laser and the rate of change in resistivity is measured after the laser pulse is terminated. The excess carrier lifetime is then calculated from the measurement. The measurement is performed using different light intensities, which is presented as a value of formed excess carriers (excess carrier density). It can be interpreted from FIG. 4 that the higher the lifetime curve is, the slower is the recombination and therefore the better is the passivation.

### EXAMPLE 1

In this example passivating deposits were formed on the surface of monocrystalline silicon substrates (for example monocrystalline wafers) according to an embodiment of the invention shown in FIG. 2.

Before bringing the substrates into the reaction space, the substrates were conditioned. During this step the possible impurities were removed from the exposed surface of the monocrystalline silicon substrate by etching for 30 s in a 1% HF solution followed by rinsing in DI-water.

After the conditioning the substrates were inserted inside the reaction space of a P400 ALD batch tool (available from Beneq OY, Finland). The substrates were positioned inside the reaction space such that the surface of the monocrystalline silicon substrate was exposed to the reaction environment.

After preparations for loading the substrates into the ALD tool, the reaction space of the ALD tool was pumped down to underpressure and a continuous flow of carrier gas was set to achieve the processing pressure of about 1 mbar (1 hPa) and the substrates were subsequently heated to the processing temperature. The temperature was stabilized to the processing temperature of 200° C. inside the reaction space by a computer controlled heating period of six hours. In this example the carrier gas discussed above, and responsible for purging the reaction space, was nitrogen (N₂). The processing temperature was sufficient to result in a thermally activated ALD-type growth and no plasma activation was employed in this example.

After the processing temperature was reached and stabilized, water was introduced as the first precursor for oxygen to the reaction space according to step a) of FIG. 2, to expose the surface of the silicon substrate to the first precursor for oxygen. After a predetermined time of introducing the first precursor for oxygen, i.e. water, a second precursor for oxygen, i.e. ozone, was simultaneously introduced to the reaction space (step a) overlapping with step b) in time). For a predetermined time both water and ozone were introduced into the reaction space after which introducing of water was terminated and the introducing of ozone was continued for a predetermined time (step b)). Subsequently the reaction space was purged.

After letting the carrier gas purge the reaction space from surplus first and second precursors for oxygen and from reaction byproducts, the resulting surface of the substrate was similarly exposed to the precursor for aluminum, i.e. trimethylaluminum, in step c). After this, the reaction space was purged again. This pulsing sequence consisting of step a), step b) and step c) was carried out once and then repeated 299 times before the process was ended and the substrates were ejected from the reaction space and from the ALD tool. The 300 “ALD cycles” resulted in a passivating deposit of aluminum oxide with a thickness of approximately 30 nm on the surface of the silicon substrate. The passivating deposit was measured to be very conformal and uniform over large surface areas.

Exposure of the surface of the substrate to a specific precursor was carried out by switching on the pulsing valve of the P400 ALD tool controlling the flow of the precursor chemicals into the reaction space. Purging of the reaction space was carried out by closing the valves controlling the flow of precursors into the reaction space, and thereby letting only the continuous flow of carrier gas flow through the reaction space. The pulsing sequence in this example was in detail as follows; 0.5 s exposure to water, 1.0 s exposure to water and ozone, 1.0 s exposure to ozone, 1.0 s purge, 0.4 s exposure to trimethylaluminum, 1.0 s purge. An exposure time and a purge time in this sequence signify a time a specific pulsing valve for a specific precursor was kept open and a time all the pulsing valves for precursors were kept closed, respectively.

### EXAMPLE 2

In this example passivating deposits were formed on the surface of monocrystalline silicon substrates (for example monocrystalline wafers) according to an embodiment of the invention shown in FIG. 1.

Before bringing the substrates into the reaction space, the substrates were conditioned. During this step the possible impurities were removed from the exposed surface of the monocrystalline silicon substrate by etching for 30 s in a 1% HF solution followed by rinsing in DI-water.

After the conditioning the substrates were inserted inside the reaction space of a P400 ALD batch tool (available from Beneq OY, Finland). The substrates were positioned inside the reaction space such that the surface of the monocrystalline silicon substrate was exposed to the reaction environment.

After preparations for loading the substrates into the ALD tool, the reaction space of the ALD tool was pumped down to underpressure and a continuous flow of carrier gas was set to achieve the processing pressure of about 1 mbar (1 hPa) and the substrates were subsequently heated to the processing temperature. The temperature was stabilized to the processing temperature of 200° C. inside the reaction space by a computer controlled heating period of six hours. In this example the carrier gas discussed above, and responsible for purging the reaction space, was nitrogen (N₂). The processing temperature was sufficient to result in a thermally activated ALD-type growth and no plasma activation was employed in this example.

After the processing temperature was reached and stabilized, water was introduced as the first precursor for oxygen to the reaction space according to step a) of FIG. 1, to expose the surface of the silicon substrate to the first precursor for oxygen. After a predetermined time of introducing the first precursor for oxygen, i.e. water, the introduction of the first precursor for oxygen was terminated and a second precursor for oxygen, i.e. ozone, was introduced to the reaction space (step a) preceding step b) in time). The introducing of ozone was continued for a predetermined time (step b)). Subsequently the reaction space was purged.

After letting the carrier gas purge the reaction space from surplus first and second precursors for oxygen and from reaction byproducts, the resulting surface of the substrate was similarly exposed to the precursor for aluminum, i.e. trimethylaluminum, in step c). After this, the reaction space was purged again.

This pulsing sequence consisting of step a), step b) and step c) was carried out once and then repeated 299 times before the process was ended and the substrates were ejected from the reaction space and from the ALD tool. The 300 “ALD cycles” resulted in a passivating deposit of aluminum oxide with a thickness of approximately 30 nm on the surface of the silicon substrate. The passivating deposit was measured to be very conformal and uniform over large surface areas.

Exposure of the surface of the substrate to a specific precursor was carried out by switching on the pulsing valve of the P400 ALD tool controlling the flow of the precursor chemicals into the reaction space. Purging of the reaction space was carried out by closing the valves controlling the flow of precursors into the reaction space, and thereby letting only the continuous flow of carrier gas flow through the reaction space. The pulsing sequence in this example was in detail as follows; 0.5 s exposure to water, 1.0 s exposure to ozone, 1.0 s purge, 0.4 s exposure to trimethylaluminum, 1.0 s purge. An exposure time and a purge time in this sequence signify a time a specific pulsing valve for a specific precursor was kept open and a time all the pulsing valves for precursors were kept closed, respectively.

It is obvious to a person skilled in the art that with the advancement of technology, the basic idea of the invention may be implemented in various ways. The invention and its embodiments are thus not limited to the examples described above; instead they may vary within the scope of the claims.

1. A method for producing a deposit on a surface of a silicon substrate, the deposit comprising aluminum oxide, wherein the method comprises in any order the alternating steps of
a) introducing into a reaction space one of water and ozone as a precursor for oxygen such that at least a portion of said precursor for oxygen gets adsorbed onto the deposition surface of the silicon substrate,
b) introducing into a reaction space the other of water and ozone as a precursor for oxygen such that at least a portion of said precursor for oxygen gets adsorbed onto the deposition surface of the silicon substrate,
c) introducing into a reaction space a precursor for aluminum such that at least a portion of the precursor for aluminum gets adsorbed onto a deposition surface of the silicon substrate, and subsequently purging the reaction space,
with the provisions that when step a) or step b) precedes step c) then the reaction space is purged before step c), and that the reaction space is not purged between step a) and step b), when step a) precedes step b) or when step b) precedes step a).

2. A method of claim 1, wherein step a) and step b) are performed sequentially in any order.

3. A method of claim 1, wherein the precursor for aluminum is selected from the group of organometallic chemicals comprising aluminum.

4. A method of claim 1, wherein the precursor for aluminum is selected from the group of trimethylaluminum, and triethylaluminum.

5. A method of claim 1, wherein the deposit is produced on the surface of the silicon substrate in a reaction space by an ALD-type process.

6. A method of claim 5, wherein the growth of the deposit in the ALD-type process is essentially thermally activated.

7. A method of claim 1, wherein the method comprises repeating at least once at least one of steps a), b) and c).

8. A method of claim 1, wherein the method comprises repeating at least once steps a), b) and c) in any order in series.

9. A method of claim 1, wherein the surface of the silicon substrate comprises monocrystalline silicon.

10. A method of claim 1, wherein the surface of the silicon substrate comprises polysilicon.

11. A method of claim 1, wherein the surface of the silicon substrate comprises microcrystalline silicon.

12. A method of claim 1, wherein the deposit on the surface of the silicon substrate is a passivating deposit.

13. A deposit on a surface of a silicon substrate, the deposit comprising aluminum oxide, obtained by a method of claim 1.

14. A deposit of claim 13, wherein the deposit on the surface of the silicon substrate is a passivating deposit.
